(19) United States
(12) Patent Application Publication
(10) Pub. No.: US 2014/0355326 A1
(43) Pub. Date: Dec. 4, 2014

(54) NON-VOLATILE MEMORY DEVICE

(71) Applicant: Kabushiki Kaisha Toshiba, Minato-ku (JP)

(72) Inventors: Takamasa OKAWA, Mie-ken (JP); Takayuki TSUKAMOTO, Mie-ken (JP); Yoichi MINEMURA, Mie-ken (JP); Hiroshi KANNO, Mie-ken (JP); Atsushi YOSHIDA, Mie-ken (JP)

(73) Assignee: Kabushiki Kaisha Toshiba, Minato-ku (JP)

(21) Appl. No.: 14/022,485

(22) Filed: Sep. 10, 2013

Related U.S. Application Data
(60) Provisional application No. 61/829,329, filed on May 31, 2013.

(51) Int. Cl. G11C 13/00; G11C 5/06

(52) U.S. Cl. CPC G11C 13/0002; G11C 5/06
USPC 365/63

(57) ABSTRACT

According to one embodiment, a non-volatile memory device includes: a plurality of first interconnects, and each of the first interconnects extending in a first direction; a plurality of second interconnects, and each of the second interconnects extending in a second direction intersecting with the first direction; a memory cell connected between each of the plurality of first interconnects and each of the plurality of second interconnects, the memory cell including a memory layer and a diode connected to the memory layer; and a control circuit capable of selecting a selection first interconnect among the first interconnects, selecting a selection second interconnect among the second interconnects, and selecting a selection memory cell connected to both the selection first interconnect and the selection second interconnect.

### CROSS-REFERENCE TO RELATED APPLICATIONS

This application is based upon and claims the benefit of priority from U.S. Provisional Patent Application 61/829,329, filed on May 31, 2013; the entire contents of which are incorporated herein by reference.

### FIELD

Embodiments described herein relate generally to a non-volatile memory device.

### BACKGROUND

A resistance-change type memory device that is one of the non-volatile memory devices is a memory device that can electrically switch at least two resistance values (for example, a high resistance value and a low-resistance value). The memory cells of the resistance-change type memory device are provided at the intersection points of bit lines and word lines intersecting with each other, and constitute a memory cell array. Each memory cell may have a selector such as a diode. Furthermore, a multi-structure memory cell array is configured by stacking memory cell arrays. In the multi-structure memory cell array, bit lines and word lines are shared by the upper and lower layers. The resistance state of the memory cell can be changed by applying a different voltage between the selected bit line and the selected word line.

However, a continuous applying the voltage may cause the degradation of the selector. When a memory cell having the degraded selector is in a non-selected state, a leak current may flow thorough the memory cell in the non-selected state. Therefore, even if another memory cell connected to the bit line or the word line connected to the memory cell having the degraded selector is brought into a selected state, a voltage applied to both ends of the selected memory cell is decreased, and thus a writing failure may be occurred. Thus, an operation of relieving the memory cell having the degraded selector is considered.

### BRIEF DESCRIPTION OF THE DRAWINGS

FIG. 1 is an example of a block diagram showing a resistance-change memory according to a first embodiment;

FIG. 2A is an example of a schematic three-dimensional view showing a memory cell array according to the first embodiment, and FIG. 2B is an example of showing the memory cell array according to the first embodiment and an equivalent circuit diagram of the memory cell array;

FIG. 3 is an example of a schematic three-dimensional view showing an example of interconnects and memory cells in the memory cell array according to the first embodiment;

FIGS. 4 to 6 are examples of schematic views showing set operation failures generated in a cross shape in the memory cell array according to the first embodiment;

FIGS. 7A to 7C are examples of diagrams showing the temporal change of the set operation failure generated in the cross shape in the memory cell array according to the first embodiment;

FIG. 8 is an example of a diagram showing the temporal change of a set operation failure rate in the memory cell array according to the first embodiment;

FIG. 9 is an example of a flowchart showing a method of driving a resistance-change memory according to the first embodiment;

FIGS. 10A and 10B are diagrams showing a state where a reverse voltage is applied between a predetermined word line and a plurality of bit lines intersecting with the predetermined word line;

FIG. 11 is an example of a flowchart showing a method of driving the resistance-change memory according to the first embodiment;

FIG. 12 is an example of a diagram showing a breakdown voltage of the diode;

FIG. 13 is an example of a schematic view showing a column replacement (bit line replacement) according to the first embodiment;

FIG. 14 is an example of a schematic view showing a row replacement according to the first embodiment;

FIG. 15 is an example of a schematic diagram showing other column replacement according to the first embodiment;

FIG. 16 is an example of a schematic view showing other row replacement according to the first embodiment;

FIG. 17A is an example of a diagram showing a relationship between a cycle number and a reset operation failure (RFN), and FIGS. 17B to 17C are examples of a diagram showing an addresses of defective memory cells in a map; and

FIG. 18 is an example of a flowchart showing a method of driving a resistance-change memory according to a second embodiment;

### DETAILED DESCRIPTION

In general, according to one embodiment, a non-volatile memory device includes: a plurality of first interconnects, and each of the first interconnects extending in a first direction; a plurality of second interconnects, and each of the second interconnects extending in a second direction intersecting with the first direction; a memory cell connected between each of the plurality of first interconnects and each of the plurality of second interconnects, the memory cell including a memory layer and a diode connected to the memory layer; and a control circuit capable of being configured to select a selection first interconnect among the first interconnects, select a selection second interconnect among the second interconnects, and select a selection memory cell connected to both the selection first interconnect and the selection second interconnect, the control circuit capable of being configured to determine whether a value on the basis of a number of memory cells whose resistance value is not changed from a first resistance value to a second resistance value lower than the first resistance state being higher than a first specified value or not, and when the value being determined to be higher than the first specified value, the selection second interconnect being inhibited.

Embodiments will now be described below with reference to the drawings. In the following description, like member are identified with like numerals, and the description of members described once will be omitted as appropriate.

### First Embodiment

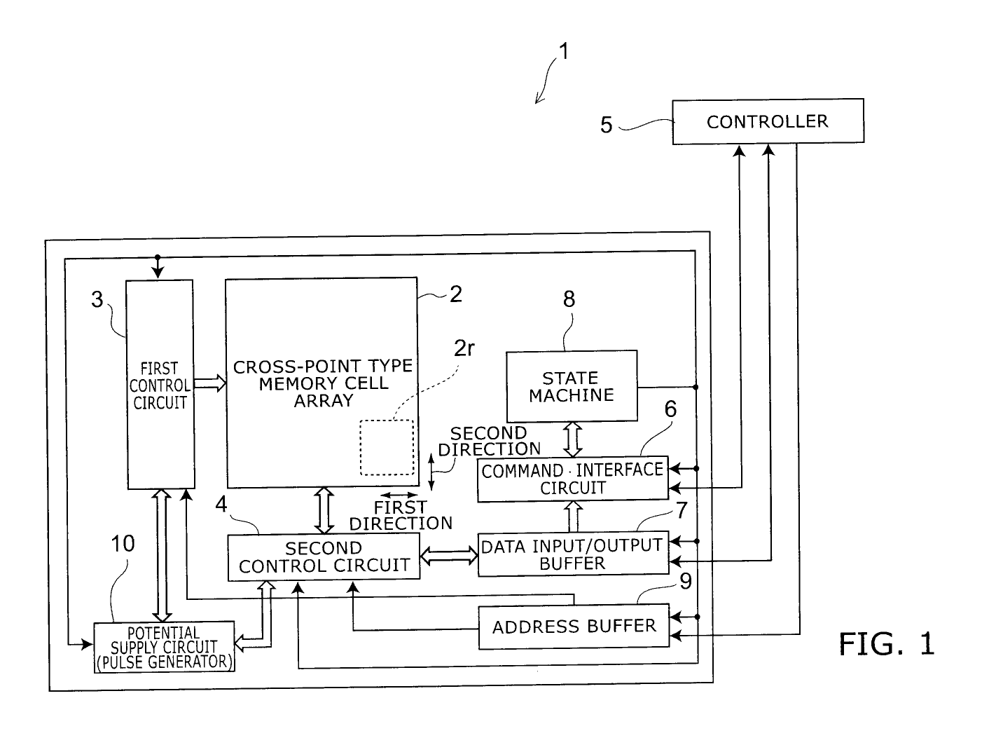

The outline of a resistance-change memory according to a first embodiment will be described using FIGS. 1 to 3.

FIG. 1 is an example of a block diagram showing the resistance-change memory according to the first embodiment.

The resistance-change memory 1 (non-volatile memory device 1) includes, for example, a cross-point type memory cell array 2. The memory cell array 2 has a redundancy region 2r on the assumption that a memory cell within the memory cell array 2 becomes defective. In the redundancy region 2r, a plurality of auxiliary rows (word lines) and a plurality of auxiliary columns (bit lines) are disposed.

At one end of a first direction of the memory cell array 2, a first control circuit 3 is disposed, and at one end of a second direction intersecting with the first direction, a second control circuit 4 is disposed.

The first control circuit 3 selects the row (word line) of the memory cell array 2 on the basis of, for example, a row address signal. The second control circuit 4 selects the column (bit line) of the memory cell array 2 on the basis of, for example, a column address signal.

The first control circuit 3 and the second control circuit 4 control writing/erasing/reading of data to/from/from memory layers (memory elements) within the memory cell array 2.

In the resistance-change memory 1, for example, writing is referred to as a set operation, and erasing is referred to as a reset operation. A resistance value in a set state is preferably different from a resistance value in a reset state.

For example, the resistance value in the set state is assumed to be lower than the resistance value in the reset state. Bringing the set state into the reset state is assumed to be the reset operation, and bringing the reset state into the set state is assumed to be the set operation.

In addition, the resistance-change memory 1 may be a multi-valued resistance-change memory in which, in the set operation, one level of a plurality of resistance value levels that can be taken by the memory layer is caused to be selectively written, and thus one memory layer stores multi-valued data (multi-level data).

A controller 5 (main control portion 5) supplies a control signal and data to the resistance-change memory 1. The control signal is input to a command•interface circuit 6, and the data is input to a data input/output buffer 7. The controller 5 may be disposed outside the resistance-change memory 1.

The command•interface circuit 6 determines, on the basis of the control signal, whether or not the data from the controller 5 (or a host or the like) is command data. When the data is the command data, the data is transferred from the data input/output buffer 7 to a state machine 8.

The state machine 8 manages the operation of the resistance-change memory 1 on the basis of a command. For example, the state machine 8 manages the set/reset operation and the reading operation on the basis of the command from the controller 5. The controller 5 can receive status information managed by the state machine 8 and determine the result of the operation in the resistance-change memory 1.

In the set/reset operation and the reading operation, the controller 5 supplies the address signal to the resistance-change memory 1. The address signal is input through an address buffer 9 to the first control circuit 3 and the second control circuit 4.

A potential supply circuit 10 outputs, with predetermined timing, for example, a voltage pulse or a current pulse needed for the set/reset operation and the reading operation on the basis of an instruction from the state machine 8. The potential supply circuit 10 includes a pulse generator, and controls, in accordance with an operation indicated by the command data and the control signal, the voltage value/current value of the voltage pulse/current pulse, and the pulse width of the voltage pulse/current pulse.

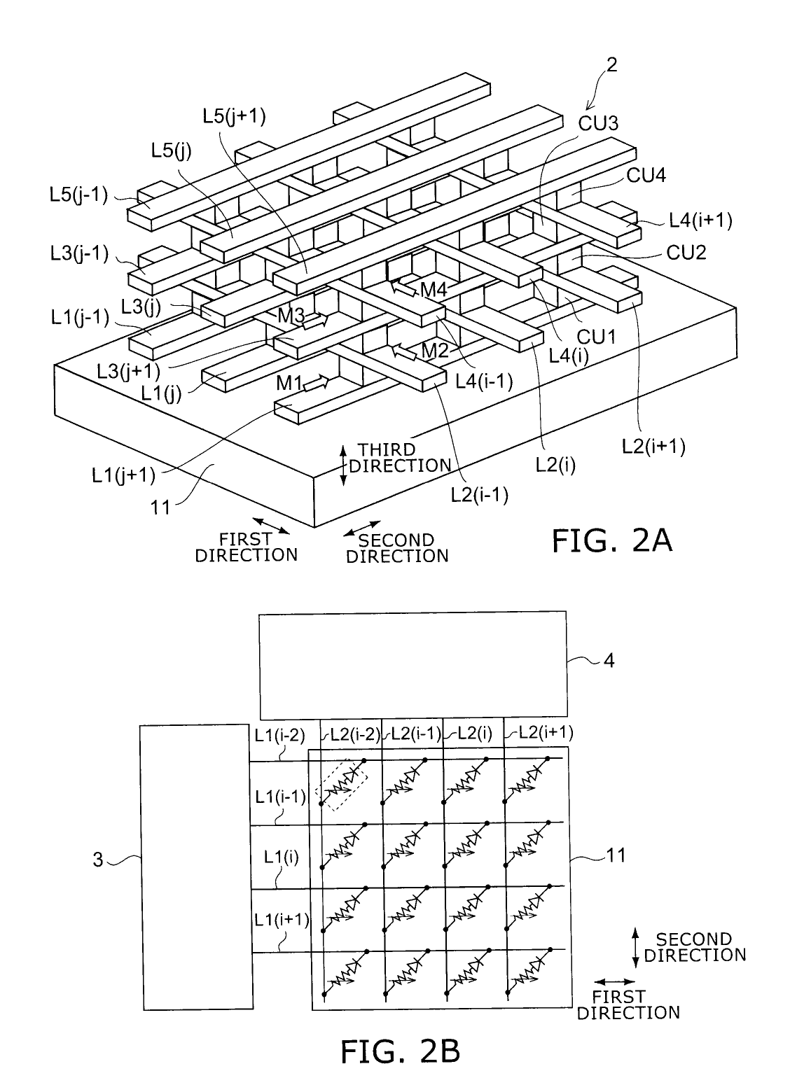

FIGS. 2A and 2B are examples of a schematic three-dimensional view showing the memory cell array according to the first embodiment.

The memory cell array 2 is disposed on a substrate 11. The substrate 11 is a semiconductor substrate (for example, a silicon substrate) or an interlayer insulting film on the semiconductor substrate. When the substrate 11 is the interlayer insulting film, on the semiconductor substrate surface below the memory cell array 2, a circuit using a field-effect transistor or the like may be provided as a peripheral circuit of the memory.

The memory cell array 2 is configured with, for example, a stacking structure of a plurality of memory cell arrays (also referred to as a memory cell layer).

FIGS. 2A and 2B show, as an example, a case where the memory cell array 2 is configured with four memory cell arrays M1, M2, M3 and M4 stacked in a third direction (direction perpendicular to the major surface of the substrate 11). The number of memory cell arrays stacked is preferably two or more. In addition, the memory cell array 2 may be configured with one memory cell array.

When a plurality of the memory cell arrays M1, M2, M3 and M4 are stacked, the address signal includes, for example, a memory cell array selection signal, the row address signal and the column address signal. The first control circuit 3 and the second control circuit 4 select one of a plurality of memory cell arrays stacked on the basis of, for example, the memory cell array selection signal. The first control circuit 3 and the second control circuit 4 can perform writing/erasing/reading of data to/from/from one of a plurality of memory cell arrays stacked or can simultaneously perform writing/erasing/reading of data to/from/from two or more or all of a plurality of memory cell arrays stacked. Furthermore, a part of the first control circuit 3, the second control circuit 4, the command•interface circuit 6, the data input/output buffer 7, the state machine 8 and the address buffer 9 may be referred to or all of them may be collectively referred to as the “control circuit.”

The memory cell array M1 is configured with a plurality of memory cells CU1 disposed in an array in the first direction and the second direction. In the same manner, the memory cell array M2 is configured with a plurality of memory cells CU2 disposed in an array, the memory cell array M3 is configured with a plurality of memory cells CU3 disposed in an array and the memory cell array M4 is configured with a plurality of memory cells CU4 disposed in an array.

The memory cells CU1, CU2, CU3 and CU4 each are configured with memory layers connected in series and non-ohmic elements.

On the substrate 11, in order from the side of the substrate 11, interconnects L1(j−1), L1(j) and L1(j+1), interconnects L2(i−1), L2(i) and L2(i+1), interconnects L3(j−1), L3(j) and L3(j+1), interconnects L4(i−1), L4(i) and L4(i+1) and interconnects L5(j−1), L5(j) and L5(j+1) are disposed.

The odd-numbered interconnects from the side of the substrate 11, that is, the interconnects L1(j−1), L1(j) and L1(j+1), the interconnects L3(j−1), L3(j) and L3(j+1) and the interconnects L5(j−1), L5(j) and L5(j+1) extend in the second direction.

The even-numbered interconnects from the side of the substrate 11, that is, the interconnects L2(i−1), L2(i) and L2(i+1) and the interconnects L4(i−1), L4(i) and L4(i+1) extend in the first direction intersecting with the second direction. These interconnects are used as the word lines and the bit lines.

The lowermost first memory cell array M1 is disposed between the first interconnects L1(j−1), L1(j) and L1(j+1) and the second interconnects L2(i−1), L2(i) and L2(i+1). In the set/reset operation and the reading operation on the memory cell array M1, one of the interconnects L1(j−1), L1(j) and L1(j+1) and the interconnects L2(i−1), L2(i) and L2(i+1) is used as the word lines, and the other is used as the bit lines.

The memory cell array M2 is disposed between the second interconnects L2(i−1), L2(i) and L2(i+1) and the third interconnects L3(j−1), L3(j) and L3(j+1). In the set/reset operation and the reading operation on the memory cell array M2, one of the interconnects L2(i−1), L2(i) and L2(i+1) and the interconnects L3(j−1), L3(j) and L3(j+1) is used as the word lines, and the other is used as the bit lines.

The memory cell array M3 is disposed between the third interconnects L3(j−1), L3(j) and L3(j+1) and the fourth interconnects L4(i−1), L4(i) and L4(i+1). In the set/reset operation and the reading operation on the memory cell array M3, one of the interconnects L3(j−1), L3(j) and L3(j+1) and the interconnects L4(i−1), L4(i) and L4(i+1) is used as the word lines, and the other is used as the bit lines.

The memory cell array M4 is disposed between the fourth interconnects L4(i−1), L4(i) and L4(i+1) and the fifth interconnects L5(j−1), L5(j) and L5(j+1). In the set/reset operation and the reading operation on the memory cell array M4, one of the interconnects L4(i−1), L4(i) and L4(i+1) and the interconnects L5(j−1), L5(j) and L5(j+1) is used as the word lines, and the other is used as the bit lines.

Here, in places where the interconnects L1(j−1), L1(j) and L1(j+1) and the interconnects L2(i−1), L2(i) and L2(i+1) intersect with each other, places where the interconnects L2(i−1), L2(i) and L2(i+1) and the interconnects L3(j−1), L3(j) and L3(j+1) intersect with each other, places where the interconnects L3(j−1), L3(j) and L3(j+1) and the interconnects L4(i−1), L4(i) and L4(i+1) intersect with each other, and places where the interconnects L4(i−1), L4(i) and L4(i+1) and the interconnects L5(j−1), L5(j) and L5(j+1) intersect with each other, each of the memory cells CU1, CU2, CU3 and CU4 is disposed. That is, in the cross-point type memory cell array 2, in the places where a plurality of interconnects are stacked continuously in the third direction, the memory cells are disposed.

When the stacked memory cell arrays are separated for each layer by the insulating films, the interconnects are not shared by the stacked memory cell arrays, and the interconnects as the word lines and the bit lines are provided, for each memory cell array in each layer. In addition, in each memory cell array, the bit lines and the word lines are shared. However, the insulating film is provided between two stacked memory cell arrays, and the bit lines and the word lines may not be shared.

FIG. 2B is an example of an equivalent circuit diagram of the memory cell array in one layer of FIG. 2A. As shown in FIG. 2B, the memory cell CU disposed between the bit line and the word line has a selector 13 and a resistance-change element 12. The selector 13 is, for example, a diode. In each of the memory cells CU, the resistance element 12 and the selector 13 are connected in series. Here, the anode side of the diode is connected to the bit line, and the cathode side is connected to the word line.

In addition, the second control circuit also has a plurality of sense amplifiers S/As. Each sense amplifier S/A is connected to the bit line. One sense amplifier S/A may be shared by a plurality of bit lines. The sense amplifier S/A detects the voltage or the current of the bit line, and can determine whether or not it is higher than a specified value.

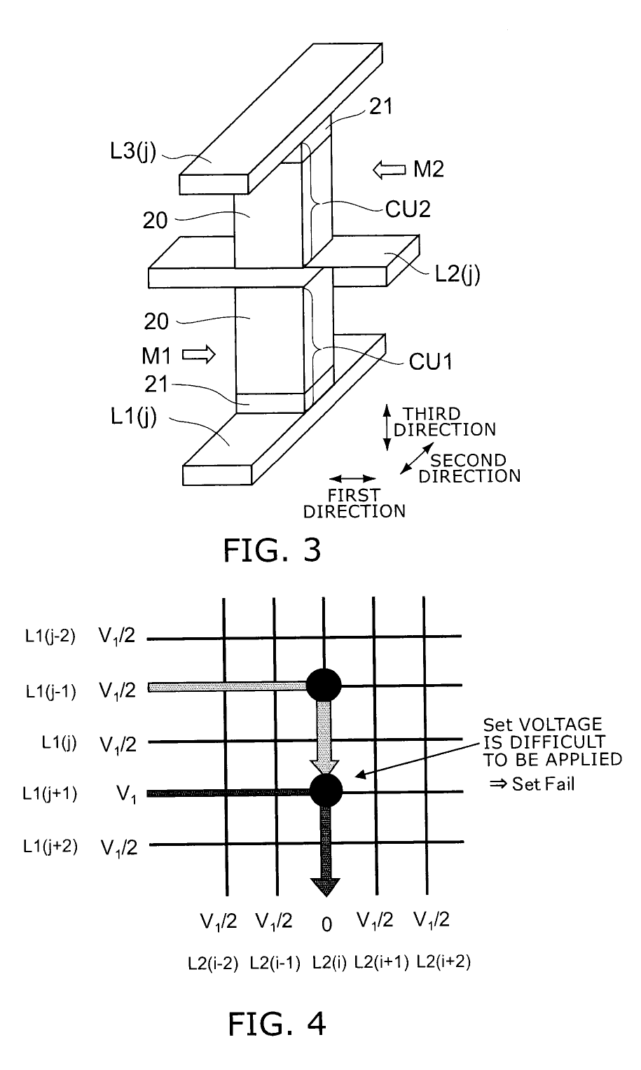

FIG. 3 is an example of a schematic three-dimensional view showing an example of the interconnects and the memory cells in the memory cell array according to the first embodiment.

Here, FIG. 3 shows the memory cells CU1 and CU2 within the two memory cell arrays M1 and M2 in FIGS. 2A and 2B. In this case, the configuration of the memory cells within the two memory cell arrays M3 and M4 in FIGS. 2A and 2B is the same as that of the memory cells within the two memory cell arrays M1 and M2 in FIGS. 2A and 2B.

The memory cells CU1 and CU2 each are configured with a memory layer (a variable resistance changing layer) 20 connected in series and a non-ohmic element. As the non-ohmic element, for example, a diode 21 (rectification element) is used.

There are a variety of patterns of the connection relationship between the memory layer 20 and the diode 21. However, in all the memory cells within one memory cell array, the connection relationship between the memory layer 20 and the diode 21 needs to be same.

In the following description, as an example, it is assumed that the interconnect extending in the first direction is the bit line and that the interconnect extending in the second direction intersecting with the first direction is the word line. The bit line is, for example, the interconnects L2(i−1), L2(i), L2(i+1), L4(i−1), L4(i) and L4(i+1) shown in FIGS. 2A and 2B. In addition, the bit line is also referred to as a first interconnect. The word line is, for example, the interconnects L1(j−1), L1(j) and L1(j+1), L3(j−1), L3(j), L3(j+1), L5(j−1), L5(j) and L5(j+1) shown in FIG. 2. Furthermore, the word line is also referred to as a second interconnect. Moreover, as described above, the names of the bit line and the word line may be replaced with each other.

As described above, the resistance-change memory 1 includes: a plurality of bit lines L2 and L4, each of which extends in the first direction; a plurality of word lines L1, L3 and L5, each of which extends in the second direction intersecting with the first direction; the memory cells CUs which are connected between each of the plurality of the bit lines L2 and L4 and each of the plurality of the word lines L1, L3 and L5; the control circuit portions (the first control circuit 3 and the second control circuit 4) which are connected to each of the plurality of the bit lines L2 and L4 and each of the plurality of the word lines L1, L3 and L5; and the controller 5 which is connected to the control circuit portions. The memory cell CU includes the memory layer 20 and the diode 21 connected to the memory layer 20. The memory layer 20 is an element that can electrically switch between at least two resistance values (for example, a high resistance state and a low resistance state).

Before explanation of a specific method of driving the resistance-change memory 1 according to the first embodiment, there will be given an explanation of set operation failures generated in a cross shape in the memory cell array, the temporal change of the set operation failure in the memory cell array according to the first embodiment, and the temporal change of a set operation failure rate in the memory cell array.

FIGS. 4 to 6 are examples of schematic views showing the set operation failures generated in a cross shape in the memory cell array according to the first embodiment.

FIGS. 4 to 6 show, as an example, the bit lines L2(i−2), L2(i−1), L2(i), L2(i+1) and L2(i+2), and the word lines L1(j−2), L1(j−1), L1(j), L1(j+1) and L1(j+2). “i” and “j” each represent a natural number.

The change in the resistance of the memory layer 20 is performed by the application of a voltage between the selected bit line and the selected word line. However, when the application of the voltage is repeated, the diode 21 may be degraded. In the following description, the diode which is degraded may be referred to as the degraded diode.

For example, FIGS. 4 to 6 show a state where the diode 21 provided between the bit line L2(i) and the word line L1(j−1) is degraded. Here, the degraded state means that the function of the diode as the selector is degraded, that is, a case or the like where the cut-off characteristics of a current are degraded at the time of reverse bias. That is, even when the memory cell is in a non-selected state, the reverse bias is applied between the bit line and word line. When the diode is not degraded, little leak current flows. However, when the diode is degraded, the function as the selector is degraded, and thus leak current flows.

For example, as shown in FIG. 4, there is generated a phenomenon in which it is not possible to perform the set operation on the memory cell provided between the bit line L2(i) and the word line L1(j+1).

For example, in order to select the memory cell CU, the control circuit can select the bit line and the word line connected to the memory cell. Here, the memory cell selected is referred to as the selected memory cell, the bit line selected is referred to as the selected bit line, the word line selected is referred to as the selected word line, a word line other than the selected word line is referred to as a non-selected word line and a bit line other than the selected bit line is referred to as a non-selected bit line. The control circuit controls the first control circuit 1 and the second control circuit 4, to thereby apply a potential of V₁/2 to each of the bit lines L2(i−2), L2(i−1), L2(i+1) and L2(i+2) and each of the word lines L1(j−2), L1(j−1), L1(j) and L1(j+2).

In this case, a potential difference between each of the bit lines L2(i−2), L2(i−1), L2(i), L2(i+1) and L2(i+2), and each of the word lines L1(j−2), L1(j−1), L1(j), L1(j+1) and L1(j+2) is 0 (V), and the resistance value of the non-selected memory cell is not changed.

In the set operation, for example, the control circuit applies V₁ (V) to the selected word line L1(j+1), and applies 0 (V) to the selected bit line L2(i).

In this case, a voltage of V₁ (V) is applied to the memory cell that performs the set operation, and this memory cell moves into a set state.

However, as shown in FIG. 4, the non-selected memory cell is also connected to the selected bit line. In addition, in the non-selected memory cell connected to the selected bit line L2(i) among the non-selected memory cells, a potential difference V₁/2 is applied to the diode as the reverse bias. Here, when the diode is not degraded, little leak current flows. However, when the diode is degraded, a relatively large amount of leak current flows even in the case of a reverse-direction bias. Consequently, leak current flows through the diode 21 provided between the bit line L2(i) and the word line L1(j−1).

Therefore, the potential difference V₁ between the bit line L2(i) and the word line L1(j+1) is low by the leak current, and thus it does not reach a target potential difference in the set operation. Consequently, it is not possible to perform the set operation on the memory cell provided between the bit line L2(i) and the word line L1(j+1). The memory cell on which it is not possible to perform the set operation is not limited to the memory cell provided between the bit line L2(i) and the word line L1(j+1). For example, in even another memory cell connected to the bit line L2(i), there is a possibility that it is not possible to perform the set operation.

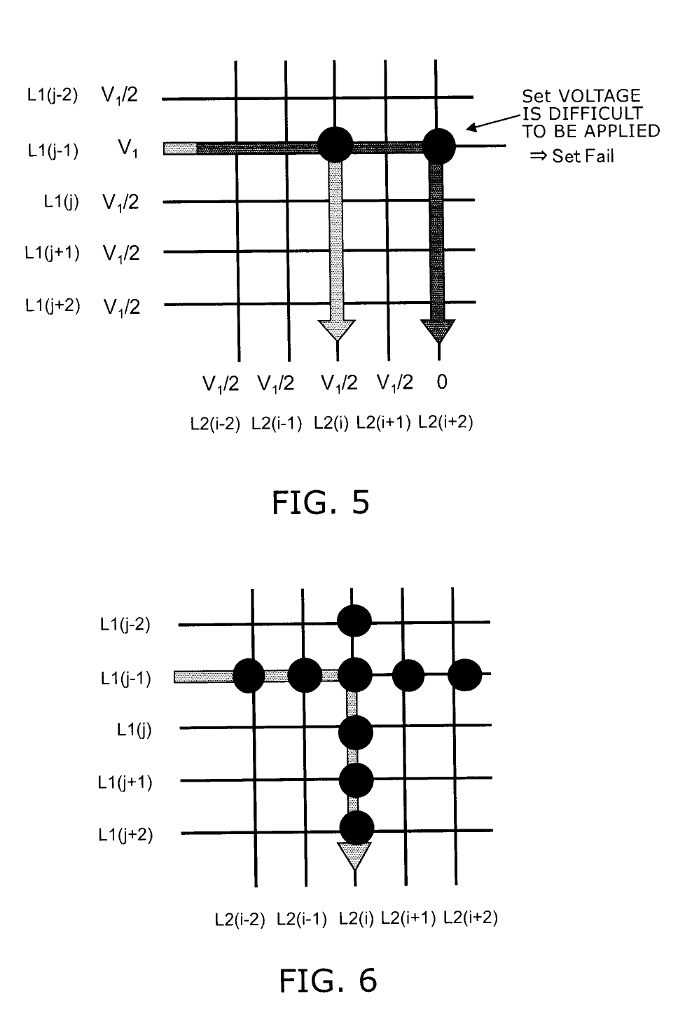

In addition, as shown in FIG. 5, there is generated a phenomenon in which it is not possible to perform the set operation on the memory cell provided between the bit line L2(i+2) and the word line L1(j−1). This is because the potential difference V₁/2 is applied as the reverse bias to the non-selected memory cell connected to the selected word line L1(j−1) among the non-selected memory cells. Here, when the diode is not degraded, little leak current flows even if the reverse-direction bias is applied. However, when the diode is degraded, leak current flows even if the reverse-direction bias is applied. Consequently, leak current flows through the diode 21 provided between the bit line L2(i) and the word line L1(j−1). Consequently, the potential of the word line L1(j−1) is decreased. Therefore, the potential difference between the bit line L2(i+2) and the word line L1(j−1) does not reach the potential difference needed in the set operation.

Thus, as shown in FIG. 6, the memory cells not changing the resistance value in the set operation exist to the memory cells connected to the bit line L2(i) and the memory cells connected to the word line L1(j−1), with the memory cell provided between the between the bit line L2(i+2) and the word line L1(j−1) being a starting point. That is, the failures are generated in a cross shape in the memory cell array.

The failure of the set operation tends to be more likely to be generated as the number of times of writing/erasing to/from the memory cell is increased.

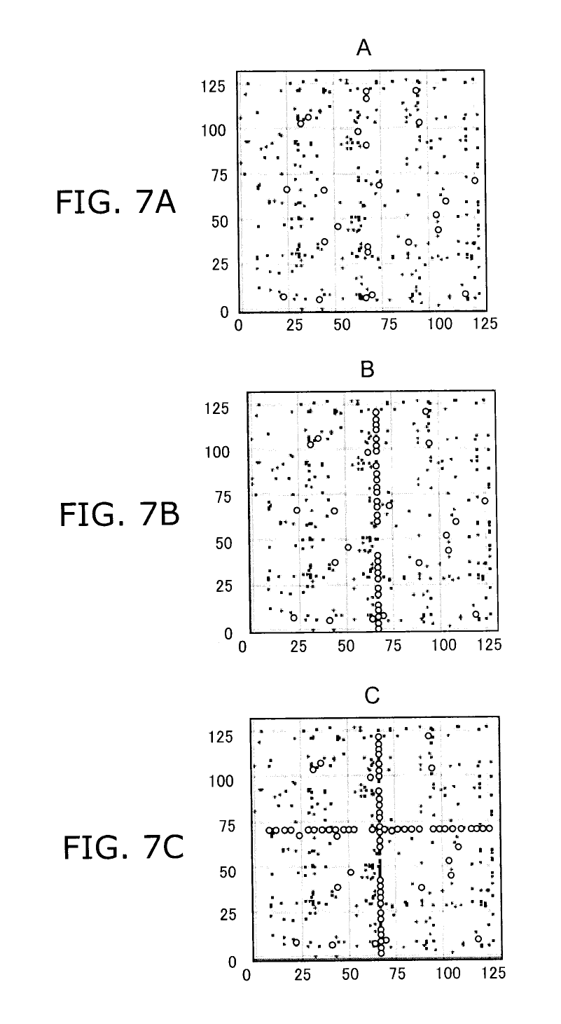

FIGS. 7A to 7C are examples of diagrams showing the temporal change of the set operation failure in the memory cell array according to the first embodiment.

In the horizontal axis of each of FIGS. 7A to 7C, the numbers of the bit lines are shown, and in the vertical axis, the numbers of the words lines are shown. In each of FIGS. 7A to 7C, for example, the memory cell array including the memory cells CUs in the Nth stage (N: a natural number) from the bottom of the memory cell array 2 are shown.

In each of FIGS. 7A to 7C, the addresses of the defective memory cells are shown in the shape of a map (Fail bit Map).

In addition, the numeral attached to the upper side of each of FIGS. 7A to 7C represents the cycle number of writing and erasing. The cycle number means that, for example, each of the set operation and the reset operation is repeated once. That is, when one memory cell performs the set operation and the reset operation once, the cycle number becomes one. FIGS. 7A to 7C show a case where the set operation and the reset operation are performed evenly on the memory cells in the memory cell array. For example, in FIG. 7A, the address of the memory cells that become defective when the cycle number of the memory cells is A are shown. Here, the cycle number A, B, and C has a relationship of 0<A<B<C.

In each of FIGS. 7A to 7C, the memory cell in which the set operation failure is generated is represented by a circle. In addition, the memory cell in which the reset operation failure is generated is represented by a dot.

As shown in FIG. 7A, when the cycle number is A, in some parts of the cross points in the memory cell array, the set operation failure and the reset operation failure are generated. This is considered to be random failures that are randomly generated with an arbitrary probability. As shown in FIG. 7B, when the cycle number is B, in certain bit lines, the set operation failure is more likely to be generated. As shown in FIG. 7C, when the cycle number exceeds C, in the predetermined word lines of certain bit lines, the set operation failure is more likely to be generated. That is, in the memory cell array, the set operation failures are generated in a cross shape.

As the cycle number becomes larger, the set operation failures tend to be generated substantially in a cross shape. In addition, the memory cell CU located in the intersection point of the cross is referred to as a center memory cell. Furthermore, the word line connected to the center memory cell may be referred to as a defective word line; the bit line connected to the center memory cell may be referred to as a defective bit line.

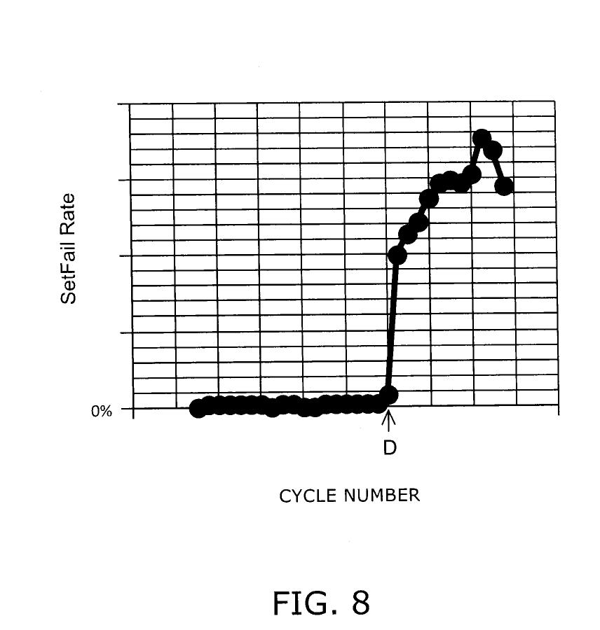

FIG. 8 is an example of a diagram showing the temporal change of the set operation failure rate in the memory cell array according to the first embodiment.

In the horizontal axis of FIG. 8, the cycle number is shown, and in the vertical axis, the set operation failure rate in the memory cell connected to the defective word line is shown.

The set operation failure rate is obtained as follows: a value obtained by dividing, by the number of memory cells performing the set operation on the memory cells connected in parallel to predetermined word lines among a plurality of word lines, the number of memory cells that have the set operation failure in this predetermined word lines is expressed in percentage.

As shown in FIG. 8, when the cycle number exceeds about D, the set operation failure rate is rapidly increased. Thereafter, the set operation failure rate is increased without being decreased. Then, the set operation failure rate becomes saturated after that.

In other words, the set operation failure rate is detected on certain word lines, and thus it is possible to predict defective word lines. The same is true for the bit lines. In other words, the set operation failure rate is detected on certain bit lines, and thus it is possible to predict defective bit lines. In addition, the defective bit lines and the defective word lines can be predicted, and thus it is possible to predict the center memory cells located at their intersections.

On the basis of the situation described above, the method of driving the resistance-change memory according to the first embodiment will be described.

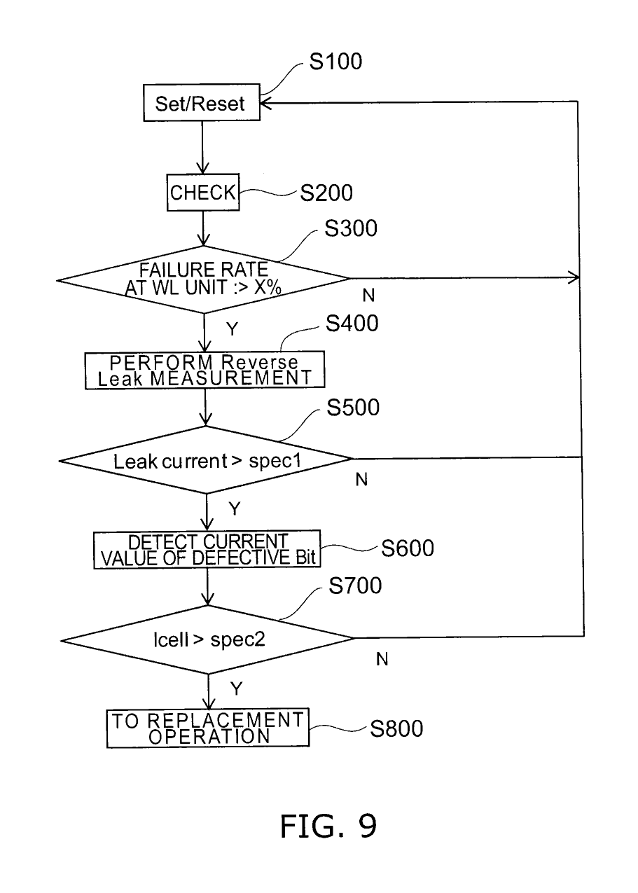

FIG. 9 is an example of a flowchart showing the method of driving the resistance-change memory according to the first embodiment.

In the first embodiment and the embodiment including the second embodiment that will be described later, the control circuit performs control on connection and disconnection between the interconnects by switching, the selection of the interconnects, control on the supply of a predetermined potential to each interconnect, reading/writing of information from/to the memory cells, the detection of the state of the memory cells, and the replacement of the interconnects or the like. In addition, the control circuit also automatically performs determination on information, computation, storage, reading and writing of the storage and the like.

First, a writing command, setting/resetting data and the address of the memory cell to be selected are sent from the controller 5 to a command•interface circuit 9, the data input/output buffer 7 and the address buffer 9. For example, the selected memory cell is assumed to be an arbitrary memory cell CU in the Nth stage from the bottom of the memory cell array 2.

Thereafter, the control circuit selects, on the basis of the address sent from the controller 5, the selected word line and the selected bit line connected to the selected memory cell, from a plurality of word lines and a plurality of bit lines. When the selected memory cell CU performs the set operation, the control circuit applies a set voltage V to the selected word line and a voltage of 0 V to the selected bit line. When the selected memory cell CU performs the reset operation, the control circuit applies a reset voltage Vr to the selected word line and a voltage of 0 V to the selected bit line. Consequently, the set voltage (first voltage) or the reset voltage is provided as a potential difference between the selected memory cells CU.

For example, it is assumed that the set voltage is V₁ (V) and the reset voltage is V₂ (V). Here, the set voltage is applied to the diode in a reverse direction, and the reset voltage is applied to the diode in a forward direction. In addition, at the time of the set operation, an intermediate voltage of V₁/2 is applied to each of the non-selected word lines and bit lines (step S100). Furthermore, at the time of the reset operation, a voltage is applied to the diode such that a potential difference applied to the non-selected memory cells is approximately 0 V or such that the diode is reverse-biased (step S100). It is possible to make the set voltage and the reset voltage have the same polarity. In addition, the set voltage and the reset voltage are made to have the same polarity, and by the change of a time during which the voltage is provided, it is also possible to perform the set operation and the reset operation.

Here, the set/reset operation is repeated until the setting/resetting data to/from the selected memory cell connected to the selected word line reaches a predetermined number, for example, one page (2112 bytes).

Then, an operation of checking the stored data is performed on the selected memory cell CU on which the writing operation has been performed (step S200).

For example, in step S200, the resistance value of each of the selected memory cell CUs connected to the selected word line. First, data (information as to whether the memory cell is brought into a set state or a reset state) to be stored in the memory cell may be stored in the data latch of the sense amplifier S/A connected to each of a plurality of bit lines. Then, for example, the control circuit applies a constant voltage to the bit line, applies a reading voltage Vr to the selected word line and can determine, from a variation in the voltage applied to the bit line, whether the memory cell is in a set state or a reset state. Furthermore, it is possible to read, at a time, the bit lines connected to the selected word lines or read them separately.

For example, the control circuit reads date of one page from the selected memory cell CU, detects consistency and inconsistency between the data and data stored in the data latch and thereby can determine whether or not writing is actually performed on the selected memory cell CU on which the writing operation has been performed.

That is, a division value is calculated by dividing the number of memory cells whose resistance is not changed from a high resistance value to a low-resistance value (second resistance value) even if the set voltage is applied among a plurality of selected memory cell CUs connected in parallel to any of the selected word lines, by the number of memory cells that have performed the set operation on a plurality of memory cells connected in parallel to any of the selected word lines. This division value can be converted into percentage, by the control circuit.

A verify operation can be performed between step S100 and step S200. Here, the verify operation is an operation of performing, when correct data is not written by performing a single set/reset operation, the set/rest operation again. Here, a case where the selected memory cell is not brought into the set state even if the verify operation is performed a specified number of times can also be specified as the set operation failure.

Then, the control circuit determine whether the calculated division value is more than a specified value (X %) or or not more than the specified value (X %) (step S300). X % is, for example, set to be 30%. The specified value (X %) is referred to as a first specified value.

When the division value is determined to be not more than the specified value (X %), the process returns to the set/reset operation described above. Then, the set/reset operation is performed on the subsequent one page of data. Furthermore, when the division value is determined to be more than the specified value (X %), the process moves to step S400.

The control circuit performs a reverse-direction leak current measurement in order to specify the memory cell having a large amount of leak current (step S400).

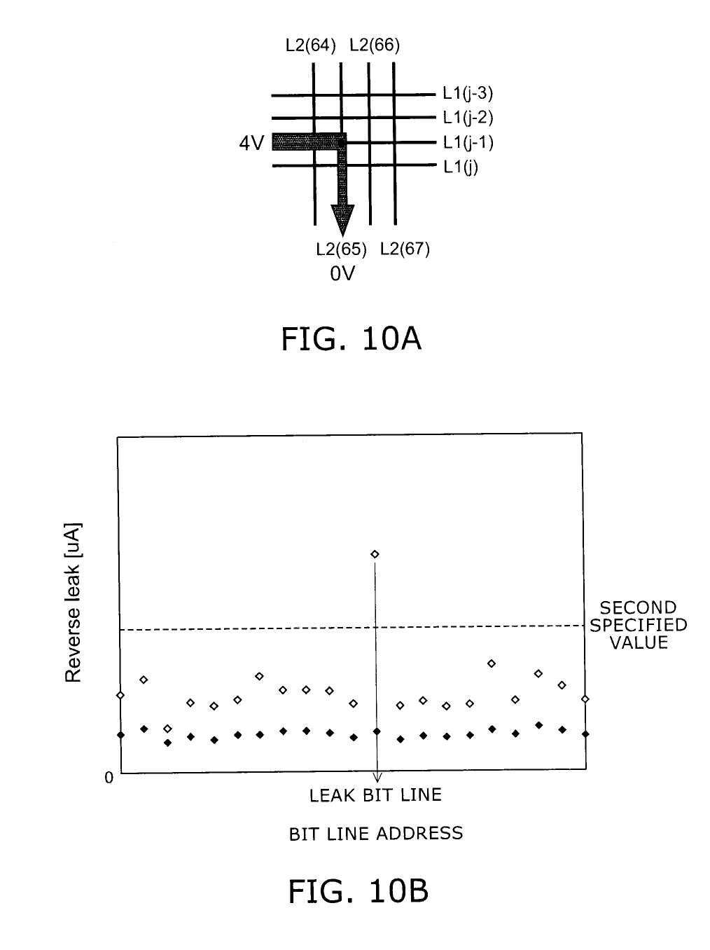

The reverse-direction leak current measurement will be described with reference to FIGS. 10A and 10B. FIG. 10A is a diagram showing a state where a reverse voltage is applied between a predetermined word line and a plurality of bit lines intersecting with the predetermined word line. For simplicity, an explanation will be given using four word lines and four bit lines.

For example, 4V₁ (V) is applied one-by-one to the word lines L1(j), L1(j−1), L1(j−2) and L1(j−3). In this state, the control circuit applies 0 (V) to each of the bit lines L2(54) to L2(74).

At this time, a current value flowing through each of a plurality of bit lines is measured. For example, the control circuit uses the sense amplifier connected to each bit line, to thereby measure the current (or a voltage drop) flowing through the bit line. Here, the control circuit determines a bit line having a large amount of leak current (step S500). For example, as shown in FIG. 10B, the control circuit determines a leak bit line whose bit line current is more than a second specified value. That is, the control circuit determines that the memory cell at the intersection point of the word line to which the reverse voltage is applied and the leak bit line is a degraded memory cell.

Here, when there is a leak in the diode 21 in the memory cell CU provided between the word line L1(j−1) and the bit line L2(65), a current flowing through the memory cell CU exceeds the second specified value, and is more than a current flowing through the memory cell CU provided between the word lines other than the word line L1(j−1) and the bit lines other than the bit line L2(65).

As described above, the control circuit can specify the position of the memory cell CU where the leak is generated. Although in FIG. 10B, the control circuit applies the voltage to one word line, 4V₁ (V) may be applied, at a time, to a plurality of word lines. Here, when the control circuit determines that there is not degraded memory cell, the process returns to the set/reset operation described above. Then, the set/reset operation is performed on the subsequent one page of data. Furthermore, when it is determined that the current value is more than the specified value (spec1), the process returns to step S600 or step S800.

Then, the same voltage as when data is read from the memory cell CU in which it is determined that the current value is more than the specified value (spec1) is applied, and thus the current value flowing through the memory cell CU is detected (step S600).

For example, the case where the memory cell CU is in a low-resistance state includes a case where the diode 21 may leak, a case where the memory layer 20 is in a low-resistance state, a case where the diode 21 may leak and the memory layer 20 is in a low-resistance state.

However, if the reset voltage whose direction is reverse to the set voltage is applied to both ends of the memory cell CU, and the memory cell CU is not changed from a low-resistance state to a high-resistance state, the diode in the memory cell CU is highly likely to leak.

Therefore, in order to redetect whether or not the diode 21 in the memory cell CU leaks, the same voltage as when the data is read from the memory cell CU is applied. Then, the current value flowing through the memory cell CU is detected. When the current value is a high value, the diode 21 in the memory cell CU can be determined to leak.

Next, whether the current value when the reading voltage is applied is more than a specified value (spec 2) or not more than the specified value (spec 2) is determined (step S700). The specified value (spec 2) is referred to as a third specified value. These steps S600 and S700 can be omitted.

Then, the control circuit replaces the bit line or the word line connected to the degraded memory cell CU with another bit line or word line (step S800).

Before the description of the operation of replacing the bit line or the word line, a center memory cell high-resistance operation is performed. For example, by breaking the center memory cell, transition from a high-resistance state to a low-resistance state is prevented.

In the first embodiment, by application of a reverse voltage (fourth voltage) whose direction is the same as the set voltage and which is higher than the set voltage, to the center memory cell CU whose current value is more than a specified value (spec 2), there is performed the degraded center memory cell high-resistance operation of increasing the resistance of the memory cell CU compared with the low-resistance value. This degraded center memory cell high-resistance operation is performed before the operation of replacing the bit line or the word line, which will be described later.

The reason why the resistance of the memory cell CU is increased compared with the low-resistance value is that, as described above, the application of a high voltage causes the memory layer 20 to be changed from the low-resistance state to the high-resistance state or that the diode 21 in the memory cell CU is broken (disconnected) by electrical or thermal stress.

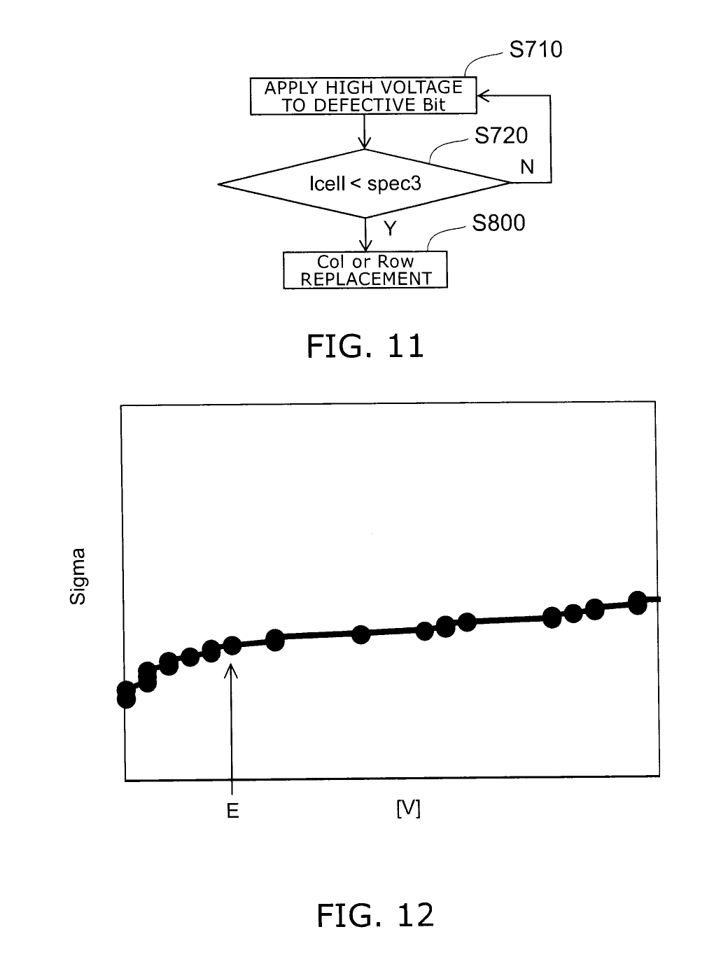

FIG. 11 is an example of a flowchart showing the method of driving the resistance-change memory according to the first embodiment.

First, the control circuit applies a high voltage (fourth voltage) whose polarity of voltage is the same as the set voltage and which is higher than the set voltage to the word line connecting the center memory cell CU having the degraded diode 21. The control circuit applies 0 V to the bit line (step S710). The control circuit can also apply a high voltage whose polarity of voltage is the same as the set voltage (whose polarity is reverse to the set voltage) and which is higher than the set voltage, to the center memory cell CU having the degraded diode 21 in the word line.

Then, the control circuit uses the sense amplifier to detect the current value of the current flowing through the center memory cell CU having the degraded diode 21. As a result, the control circuit determines whether the current value is less than a specified value (spec3) or not less than the specified value (spec3) (step S720). The specified value (spec3) is referred to as a fourth specified value.

The case where the current value is not less than the specified value (spec3) means that the memory layer 20 is not changed from the low-resistance state to the high-resistance state or that the memory cell is not broken (disconnected). Therefore, in this case, the high voltage is applied again. This operation can be repeated until the storage cell is broken.

In contrast, the case where the current value is less than the specified value (spec3) means that the memory layer 20 is not changed from the low-resistance state to the high-resistance state or that the memory cell is broken (disconnected). Therefore, in this case, the process moves to the operation of replacing the bit line or the word line.

FIG. 12 is an example of a diagram showing the breakdown voltage of the diode.

The vertical axis of FIG. 12 represents a probability of the diode that is broken among a plurality of diodes. It is assumed that the diode is the same as that mounted in the memory cell array 2.

The horizontal axis of FIG. 12 represents a reverse-direction bias (reverse voltage) applied to the diode of the memory cell, and the vertical axis represents a ratio of the memory cell that is broken by application of the reverse voltage to the diode of the memory cell.

For example, at the time of application of a voltage of E (V) to the diode, about 20% of the diode is broken. Furthermore, as the reverse voltage is increased, the ratio of the broken diode is further increased.

Consequently, in order to break the diode, there is obtained a result in which the application of a voltage of 10 (V) or more is preferable. Furthermore, in order to reliably break the diode, the reverse voltage may be applied a plurality of times. For example, when the diode is not broken by the first application of the reverse voltage, the reverse voltage is stepped up or the application time of the reverse voltage is increased, and thus it is possible to perform the second application of the reverse voltage.

Next, a specific example of the operation of replacing the bit line or the word line will be described.

### Replacement Example 1

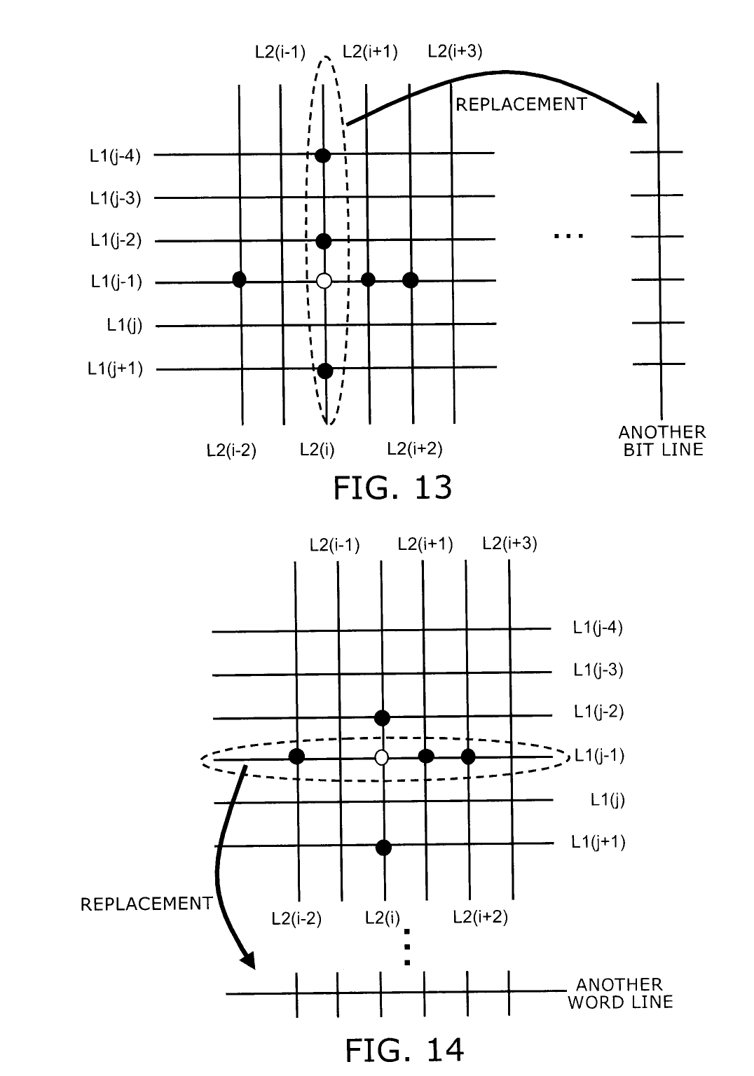

FIG. 13 is an example of a schematic view showing column replacement (bit line replacement) according to the first embodiment.

For example, the resistance of the memory cell CU is increased compared with the low-resistance value (second resistance value), and thereafter the bit line connected to the center memory cell CU is replaced with another bit line.

For example, it is assumed that the center memory cell CU is present between the bit line L2(i) and the word line L1(j−1). In this case, the bit line L2(i) is replaced with the other bit line. The other bit line is disposed in the redundancy region 2r.

### Replacement Example 2

Unlike replacement example 1, row replacement is performed.

FIG. 14 is an example of a schematic view showing the row replacement according to the first embodiment.

For example, the resistance of the center memory cell CU is increased compared with the low-resistance value (second resistance value), and thereafter the word line connected to the memory cell CU whose current value is more than the specified value (spec2) is replaced with another bit line.

For example, the memory cell CU whose current value is more than the specified value (spec2) is present between the bit line L2(i) and the word line L1(j−1). In this case, the word line L1(j−1) is replaced with the other bit line. The other word line is disposed in the redundancy region 2r.

### Replacement Example 3

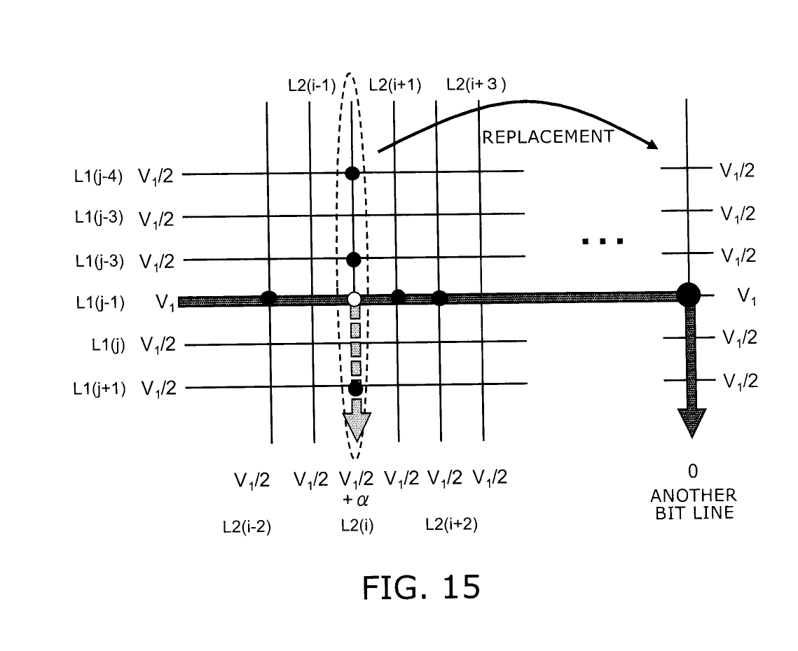

This is an example of a case where column replacement is performed without the center memory cell being broken. FIG. 15 is an example of a schematic diagram showing other column replacement according to the first embodiment.

Here, when the column replacement is performed without the center memory cell being broken, a leak is generated from the center memory cell at the time of the set operation, with the result that the voltage of the selected word line may be lowered. Therefore, an example will be described where it is possible to perform the set operation/the reset operation on a spare memory cell without the center memory cell being broken. For example, an offset bias voltage is applied to the bit line such that a potential difference applied between the bit line connected to the center memory cell CU and the word line connected to the center memory cell CU is lower than those of other non-selected memory cells.

Specifically, a bias potential is applied to the bit line L2(i) such that a potential difference applied between the bit line L2(i) and the word line L1(j−1) is lower than V₁/2. For example, a potential of V₁ (V) is applied to the word line L1(j−1), and a potential of (V₁ (V)/2)+α is applied to the bit line L2(i). Thus, a potential difference in the degraded memory cell CU is (V₁ (V)/2)−α, and is lower than a potential difference in the non-selected memory cell CU connected to the word line L1(j−1). Consequently, the reverse-direction leak current in the center memory cell CU is suppressed. Here, α is adjusted to a value by which erroneous set/erroneous rest is not generated by the flow of a forward-direction current through the other non-selected memory cells connected to the selected bit line.

That is, an offset bias is applied to the bit line L2(i) such that, when the redundancy in the column replacement is performed, the reverse-direction current is suppressed at the time of writing in the defective memory cell without the degraded memory cell CU being brought into a high-resistance state.

### Replacement Example 4

This is an example of a case where row replacement is performed without the center memory cell being broken.

Here, when the row replacement is performed without the center memory cell being broken, a leak is generated from the center memory cell at the time of the set operation, with the result that the voltage of the selected bit line may be increased. Therefore, there will be described an example in which it is made possible to perform the set operation/the reset operation on the spare memory cell without the center memory cell being broken.

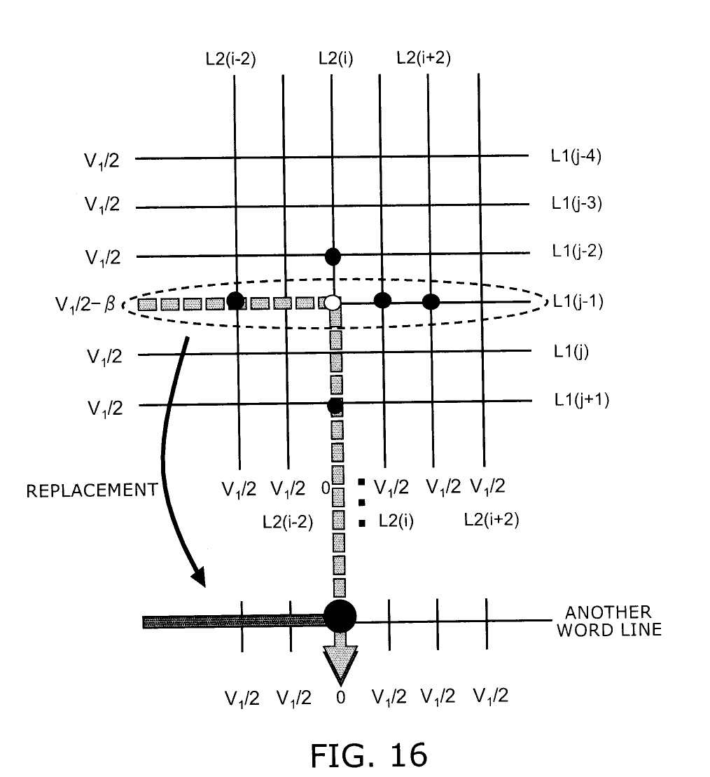

FIG. 16 is an example of a schematic view showing the row replacement according to the first embodiment.

For example, an offset bias potential is applied to the word line such that a voltage difference applied between the bit line connected to the center memory cell CU and the word line connected to the center memory cell CU becomes lower than other non-selected memory cell.

Specifically, the offset bias potential is applied to the word line L1(j−1) such that a potential difference applied between the bit line L2(i) and the word line L1(j−1) is lower than V₁/2. For example, a potential of (V₁ (V)/2)−β is applied to the word line L1(j−1), and a potential of 0 (V) is applied to the bit line L2(i). Therefore, a potential difference in the degraded memory cell CU becomes (V₁ (V)/2)+β, and becomes lower than a potential difference in the non-selected memory cell CU connected to the word line L1(j−1). Consequently, the reverse-direction leak current in the center memory cell CU is suppressed. Here, β is adjusted to a value by which there is not generated erroneous set/erroneous rest by the flow of a forward-direction current through the non-selected memory cell connected to the selected bit line.

That is, an offset bias is applied to the word line L1(j−1) such that, when the redundancy in the column replacement is performed, the reverse-direction current is suppressed at the time of writing in the defective memory cell without the degraded memory cell CU being brought into a high-resistance state.

### Second Embodiment

In a second embodiment, redundancy is performed with attention focused on the point where the center memory cell which causes a failure in a cross shape causes a reset failure.

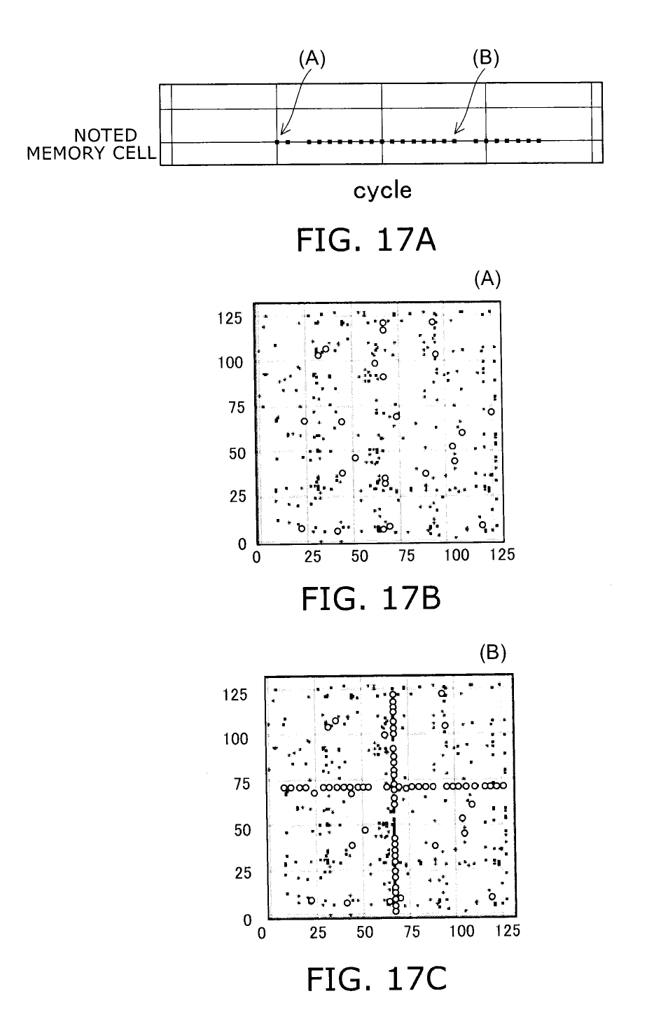

FIG. 17A is an example of a diagram showing a relationship between the cycle number and the reset operation failure (RFN); FIGS. 17B to 17C are examples of a diagram showing the addresses of defective memory cells in a map.

FIG. 17B is a diagram showing, in a map, the addresses of defective memory cells at the time of (A) of FIG. 17A. FIG. 17C is a diagram showing, in a map, the addresses of defective memory cells at the time of (B) of FIG. 17A.

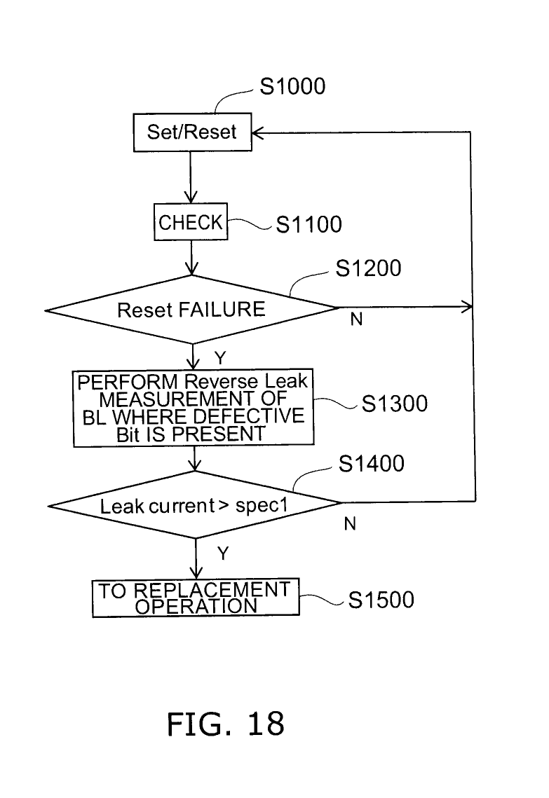

As shown in FIG. 17A, the reset failure (failure in which the state is not changed to the high-resistance state) is generated when the writing cycle is performed on the noted memory cell A) times. In the initial state, as shown in FIG. 18B, no failure in a cross shape is generated.

However, even after the writing cycle is performed on the noted memory cell A) times, the reset failure is substantially continuously generated. Here, when the writing cycle is performed B) times, as shown in FIG. 17B, the addresses of defective memory cells are brought into a state of being in a cross shape. In the memory cells connected to the defective bit lines and the defective word lines, the set operation failure is generated. The noted memory cell is the memory cell that is located in the center of the failures in a cross shape.

That is, before the generation of the set operation failures in a cross shape, the memory cell located in the cross-shaped intersection point is brought into a state of the set operation failure. Thereafter, when the cycle number is increased, the memory cell in which the reset failure is substantially continuously generated serves as the degraded memory cell.

In the second embodiment, this characteristic is utilized. For example, before the generation of the set operation failures in a cross shape, it is assumed that the memory cell CU causing the reset operation may serve as the center memory cell located in the cross-shaped intersection point, and the following processing is performed on the memory cell CU causing the reset operation failure.

For example, when the reset operation failure is generated in a certain memory cell CU, the reverse-direction current of this memory cell CU is measured. When the address where the bit line having the reverse-direction current higher than a specified value agrees with the address where the reset operation failure is generated, the memory cell of this address is detected on the assumption that the memory cell serves as the center memory cell. Thereafter, the replacement operation is performed as described above.

FIG. 18 is an example of a flowchart showing a method of driving a resistance-change memory according to the second embodiment.

First, on any of the memory cells CU of the memory cell array including the memory cells CU in the Nth stage from the bottom of the memory cell array 2, the setting/resetting (set/reset operation) of information is performed (step S1000). For example, the set voltage (first voltage) or the reset voltage is applied to both ends of the memory cell CU which is provided between any of a plurality of word lines and any of a plurality of bit lines and whose resistance is a high-resistance value (first resistance value). It is assumed that the set voltage is V₁ (V) and the reset voltage is Vᵣ (V).

Next, an operation of checking the stored data is performed on the memory cell CU on which the writing operation has been performed (step S1100).

Since the operations in step S1000 and step S1100 are substantially the same as in step S100 and step S200 in the first embodiment, the detailed description of the operations will be omitted.

Then, among a plurality of memory cells CUs connected in parallel to any one of a plurality of word lines, the control circuit determines the memory cell CU in which, even if the reset voltage is applied, its resistance does not reach the first resistance value (step S1200).

The reverse-direction leak current measurement is performed in the same manner as that described using FIGS. 10A and 10B described above (step S1300).

Then, the use of the bit line or the word line connected to the memory cell CU in which it is determined that the current value is higher than the specified value (spec1) is inhibited. Use inhibition includes the replacement operation described above (step S1500).

Furthermore, as the replacement operation, the replacement examples 1 to 4 in the first embodiment can be applied.

As described above, in the embodiment, in order to solve the generation of the set operation failures in a cross shape in the cross-point resistance-change memory cell array, there is provided the control portion which previously detects defective elements, which inhibits the use of the interconnects connected to the center memory cell, and which performs redundancy. Because of this, the failure caused by the degradation of the resistance-change memory cell is efficiently relieved.

The embodiments have been described above with reference to examples. However, the embodiments are not limited to these examples. More specifically, these examples can be appropriately modified in design by those skilled in the art. Such modifications are also encompassed within the scope of the embodiments as long as they include the features of the embodiments. The components included in the above examples and the layout, material, condition, shape, size and the like thereof are not limited to those illustrated, but can be appropriately modified.

The term “on” in “a portion A is provided on a portion B” refers to the case where the portion A is provided on the portion B such that the portion A is in contact with the portion B and the case where the portion A is provided above the portion B such that the portion A is not in contact with the portion B.

Furthermore, the components included in the above embodiments can be combined as long as technically feasible. Such combinations are also encompassed within the scope of the embodiments as long as they include the features of the embodiments. In addition, those skilled in the art could conceive various modifications and variations within the spirit of the embodiments. It is understood that such modifications and variations are also encompassed within the scope of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A non-volatile memory device comprising:
a plurality of first interconnects, and each of the first interconnects extending in a first direction;
a plurality of second interconnects, and each of the second interconnects extending in a second direction intersecting with the first direction;
a memory cell connected between each of the plurality of first interconnects and each of the plurality of second interconnects, the memory cell including a memory layer and a diode connected to the memory layer; and
a control circuit capable of being configured to select a selection first interconnect among the first interconnects, select a selection second interconnect among the second interconnects, and select a selection memory cell connected to both the selection first interconnect and the selection second interconnect,
the control circuit capable of being configured to determine whether a value on the basis of a number of memory cells whose resistance value is not changed from a first resistance value to a second resistance value lower than the first resistance state being higher than a first specified value or not, and
when the value being determined to be higher than the first specified value, the selection second interconnect being inhibited.

2. The device according to claim 1, wherein the control circuit is capable of being configured to apply a first potential difference to the selection memory cell when the memory cell is changed from the first resistance state to the second resistance state, and
when the value is determined to be not more than the first specified value, the control circuit performs a first operation such as applying a second potential difference higher than the first potential difference to the selection memory cell.

3. The device according to claim 2, wherein, after the first operation, the control circuit capable of being configured to replace the selection second interconnect with another second interconnect of the second interconnects.

4. The device according to claim 1, wherein the control circuit is capable of being configured to apply a non-selected voltage to any of the plurality of second interconnects other than the selection second interconnect at a time of a writing or erasing operation, and
the control circuit is capable of being configured to apply, at the time of set or reset operation, a second non-selected voltage lower than the non-selected voltage to the inhibited second interconnect.

5. A non-volatile memory device comprising:
a plurality of first interconnects, and each of the first interconnects extending in a first direction;
a plurality of second interconnects, each of the second interconnects extending in a second direction intersecting with the first direction;
a memory cell connected between each of the plurality of first interconnects and each of the plurality of second interconnects, the memory cell including a memory layer and a diode connected to the memory layer; and
the control circuit portion capable of being configured to select a selection first interconnect among the plurality of first interconnects, select a selection second interconnect among the plurality of second interconnects, and select a selection memory cell connected to both the selection first interconnect and the selection second interconnect among a plurality of memory cells,
the control circuit capable of being configured to
determine a defective memory cell whose resistance value being not changed from a first resistance value to a second resistance value higher than the first resistance state among a plurality of memory cells connected to the selection second interconnect,
measure a leak current in the defective memory cell, and
inhibit a first interconnect or a second interconnect connected to the memory cell when the leak current being determined to be larger than the first specified value.

6. The device according to claim 5, wherein the control circuit is capable of being configured to apply a first potential difference to the selection memory cell when the memory cell is changed from the first resistance state to the second resistance state, and
when the leak current is determined to be larger than the first specified value, the control circuit is capable of being configured to perform a first operation such as applying a second potential difference higher than the first potential difference to the defective memory cell.

7. The device according to claim 6, wherein, after the first operation, the control circuit is capable of being configured to replace the selection second interconnect with another second interconnect of the plurality of second interconnects.

8. The device according to claim 5, wherein the control circuit is capable of being configured to apply a non-selected voltage to any of the plurality of second interconnects other than the selection second interconnect at a time of a writing or erasing operation, and
the control circuit is capable of being configured to apply, at the time of set or reset operation, a second non-selected voltage lower than the non-selected voltage to the second interconnect, and the second interconnect is inhibited.
